(19) United States
(12) Patent Application Publication
(10) Pub. No.: US 2014/0175371 A1
(43) Pub. Date: Jun. 26, 2014

(54) VERTICAL CROSS-POINT EMBEDDED MEMORY ARCHITECTURE FOR METAL-CONDUCTIVE OXIDE-METAL (MCOM) MEMORY ELEMENTS

(71) Applicants: Elijah V. Karpov, Santa Clara, CA (US); Brian S. Doyle, Portland, OR (US); Uday Shah, Portland, OR (US); Robert S. Chau, Portland, OR (US)

(72) Inventors: Elijah V. Karpov, Santa Clara, CA (US); Brian S. Doyle, Portland, OR (US); Uday Shah, Portland, OR (US); Robert S. Chau, Portland, OR (US)

(21) Appl. No.: 13/723,876

(22) Filed: Dec. 21, 2012

(51) Int. Cl. H01L 27/24; H01L 45/00

(52) U.S. Cl. CPC H01L 27/2481; H01L 45/16
USPC 257/5; 438/381

(57) ABSTRACT

Vertical cross-point embedded memory architectures for metal-conductive oxide-metal (MCOM) memory elements are described. For example, a memory array includes a substrate. A plurality of horizontal wordlines is disposed in a plane above the substrate. A plurality of vertical bitlines is disposed above the substrate and interposed with the plurality of horizontal wordlines to provide a plurality of cross-points between ones of the plurality of horizontal wordlines and ones of the plurality of vertical bitlines. A plurality of memory elements is disposed in the plane above the substrate, one memory element disposed at each cross-point between the corresponding wordline and bitline of the cross-point.

### TECHNICAL FIELD

Embodiments of the invention are in the field of memory devices and, in particular, vertical cross-point embedded memory architectures for metal-conductive oxide-metal (MCOM) memory elements.

### BACKGROUND

For the past several decades, the scaling of features in integrated circuits has been a driving force behind an ever-growing semiconductor industry. Scaling to smaller and smaller features enables increased densities of functional units on the limited real estate of semiconductor chips. For example, shrinking transistor size allows for the incorporation of an increased number of memory devices on a chip, lending to the fabrication of products with increased capacity. The drive for ever-more capacity, however, is not without issue. The necessity to optimize the performance of each device becomes increasingly significant.

Embedded SRAM and DRAM have problems with non-volatility and soft error rates, while embedded FLASH memories require additional masking layers or processing steps during manufacture, require high-voltage for programming, and have issues with endurance and reliability. Nonvolatile memory based on resistance change, known as RRAM/ReRAM, typically operates at voltages greater than 1V, typically requires a high voltage (>1V) forming step to form a filament, and typically have high resistance values limiting read performance. For low voltage non-volatile embedded applications, operating voltages less than 1V and compatible with CMOS logic processes may be desirable or advantageous.

Thus, significant improvements are still needed in the area of nonvolatile device manufacture and operation.

### BRIEF DESCRIPTION OF THE DRAWINGS

FIG. 1A illustrates an angled three-dimensional view of a first conventional horizontally stacked cross-point memory array.

FIG. 1B illustrates an angled three-dimensional view of a second conventional horizontally stacked cross-point memory array.

FIGS. 2A-2C illustrate angled three-dimensional views of key fabrication operations in a method of fabricating a vertical cross-point array with conductive oxide random access memory (CORAM) type memory elements, in accordance with an embodiment of the present invention.

FIG. 3 illustrates an angled three-dimensional view of a vertical cross-point array with conductive oxide random access memory (CORAM) type memory elements, in accordance with an embodiment of the present invention.

FIG. 4A illustrates an angled three-dimensional view of a conventional two-memory layer horizontally stacked cross-point memory array.

FIG. 4B illustrates an angled three-dimensional view of a vertical cross-point array with conductive oxide random access memory (CORAM) type memory elements, in accordance with an embodiment of the present invention.

FIGS. 5A-5K illustrate angled three-dimensional views of various fabrication operations in a method of fabricating a vertical cross-point array with conductive oxide random access memory (CORAM) type memory elements, in accordance with an embodiment of the present invention.

FIG. 6 illustrates a portion of a vertical cross-point array showing the key features of a horizontal wordline (WL), a vertical bitline (BL), and a memory/selector device at a cross-point of the horizontal wordline (WL) and the vertical bitline (BL), in accordance with an embodiment of the present invention.

FIG. 7 illustrates an operational schematic representing a changing of states for an anionic-based metal-conductive oxide-metal (MCOM) memory element, in accordance with an embodiment of the present invention.

FIG. 8 illustrates a schematic representation of resistance change in a conductive oxide layer induced by changing the concentration of oxygen vacancies in the conductive oxide layer, in accordance with an embodiment of the present invention.

FIG. 9 illustrates an operational schematic representing a changing of states for a cationic-based metal-conductive oxide-metal (MCOM) memory element, in accordance with an embodiment of the present invention.

FIG. 10 illustrates a schematic representation of resistance change in a cationic-based conductive oxide layer induced by changing the concentration of cation vacancies in the conductive oxide layer, using an example of material with composition of LiₓCoO₂, in accordance with an embodiment of the present invention.

FIG. 11 illustrates a schematic of a memory bit cell which includes a metal-conductive oxide-metal (MCOM) memory element, in accordance with an embodiment of the present invention.

FIG. 12 illustrates a block diagram of an electronic system, in accordance with an embodiment of the present invention.

FIG. 13 illustrates a computing device in accordance with one implementation of the invention.

### DESCRIPTION OF THE EMBODIMENTS

Vertical cross-point embedded memory architectures for metal-conductive oxide-metal (MCOM) memory elements are described. In the following description, numerous specific details are set forth, such as specific memory element arrays and conductive oxide material regimes, in order to provide a thorough understanding of embodiments of the present invention. It will be apparent to one skilled in the art that embodiments of the present invention may be practiced without these specific details. In other instances, well-known features, such as completed integrated circuit design layouts, are not described in detail in order to not unnecessarily obscure embodiments of the present invention. Furthermore, it is to be understood that the various embodiments shown in the Figures are illustrative representations and are not necessarily drawn to scale.

One or more embodiments are directed to vertical cross-point embedded memory architectures. Such embodiments may have applications for one or more of cross-point memory, embedded memory, memory, memory arrays, resistive change RAM, RRAM, selector based memory. One or more embodiments described herein are directed to structures for and approaches to using low voltage embedded memory. The memory is based on conductive oxide and electrode stacks. In one or more embodiments, the structural architecture of each memory element in an array is based on a junction-free arrangement, in that a non-conducting layer is not used in the functional element of the memory stack. More specifically, in an embodiment, a metal-conductive oxide-metal (MCOM) structure is implemented to fabricate a resistance change memory (often referred as RRAM) based architecture, e.g., instead of a metal-dielectric (insulating) oxide-metal (MIM) based structure. The latter type is conventionally used for state of the art RRAM devices. For example, a conventional RRAM device may be based on a metal-HfOₓ-metal structure.

Nonvolatile memory elements based on resistance change, such as spin torque transfer memory (STTM) or phase change memory (PCM) can be incorporated as embedded memory arrays. The density of such arrays can be significantly increased (e.g., cell size decreased to less than 4F2) if the thin film-based selector element is placed in series with the memory element at each cross-section of bitline and wordline since the memory layers can be stacked on top of each other. However, such multilayered arrays are typically associated with high cost.

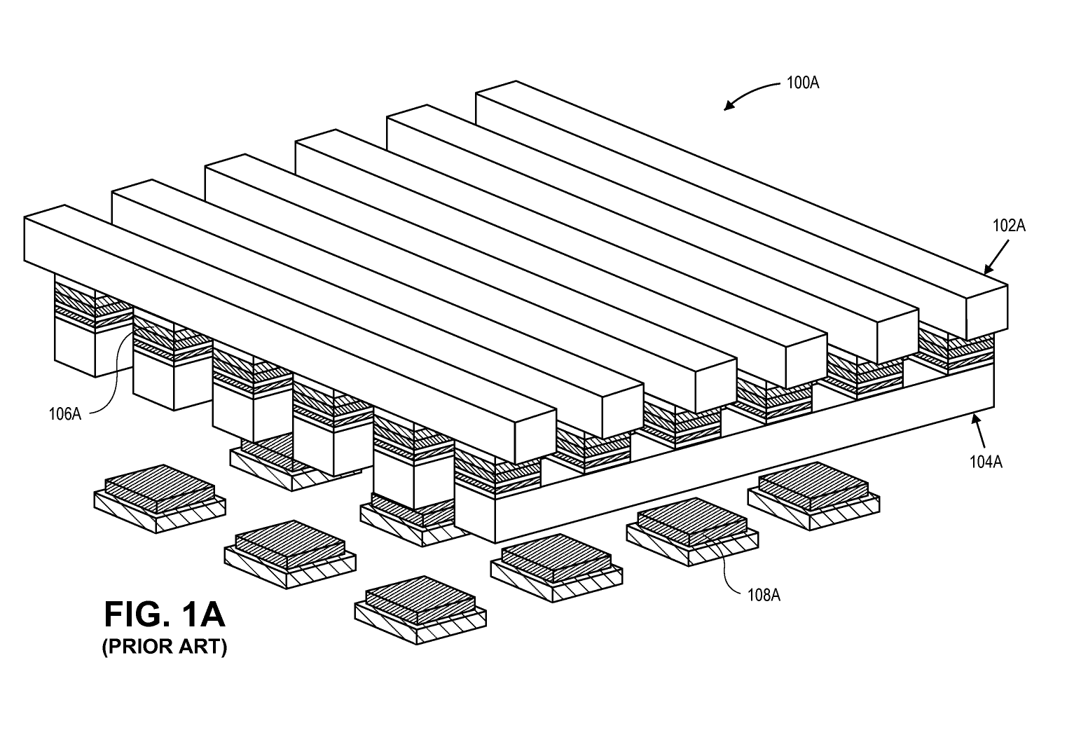

In order to illustrate the concepts herein, FIGS. 1A and 1B illustrate angled three-dimensional views of conventional horizontally stacked cross-point memory arrays 100A and 100B, respectively. The arrays 100A and 100B are based on N layers requiring 2N patterning operations. In a first example, array 100A of FIG. 1A includes one layer of memory elements and its fabrication involves two patterning operations. The array 100A includes horizontal wordlines 102A, horizontal bitlines 104A, and memory elements 106A in between the horizontal wordlines 102A and horizontal bitlines 104A. Additionally, selectors 108A are disposed below the horizontal wordlines 102A and horizontal bitlines 104A. In a second example, array 100B of FIG. 1B includes two layers of memory elements and its fabrication involves four patterning operations. The array 100B includes horizontal wordlines 102B, two layers of horizontal bitlines 104B, and two layers of memory elements 106B in between the horizontal wordlines 102B and horizontal bitlines 104B. Additionally, selectors 108B are disposed below the horizontal wordlines 102B and horizontal bitlines 104B.

By contrast to the arrays of FIGS. 1A and 1B, in accordance with one or more embodiments of the present invention, described herein are architectures and processes of fabricating vertical cross-point arrays. The arrays may be based on thin film selectors and resistance change memory. The vertical nature of the architecture allows fabrication of multilayered arrays using fewer patterning steps than state of the art cross-point arrays. For example, in one embodiment, two patterning operations are used versus 2N patterning operations where N is number of memory layers.

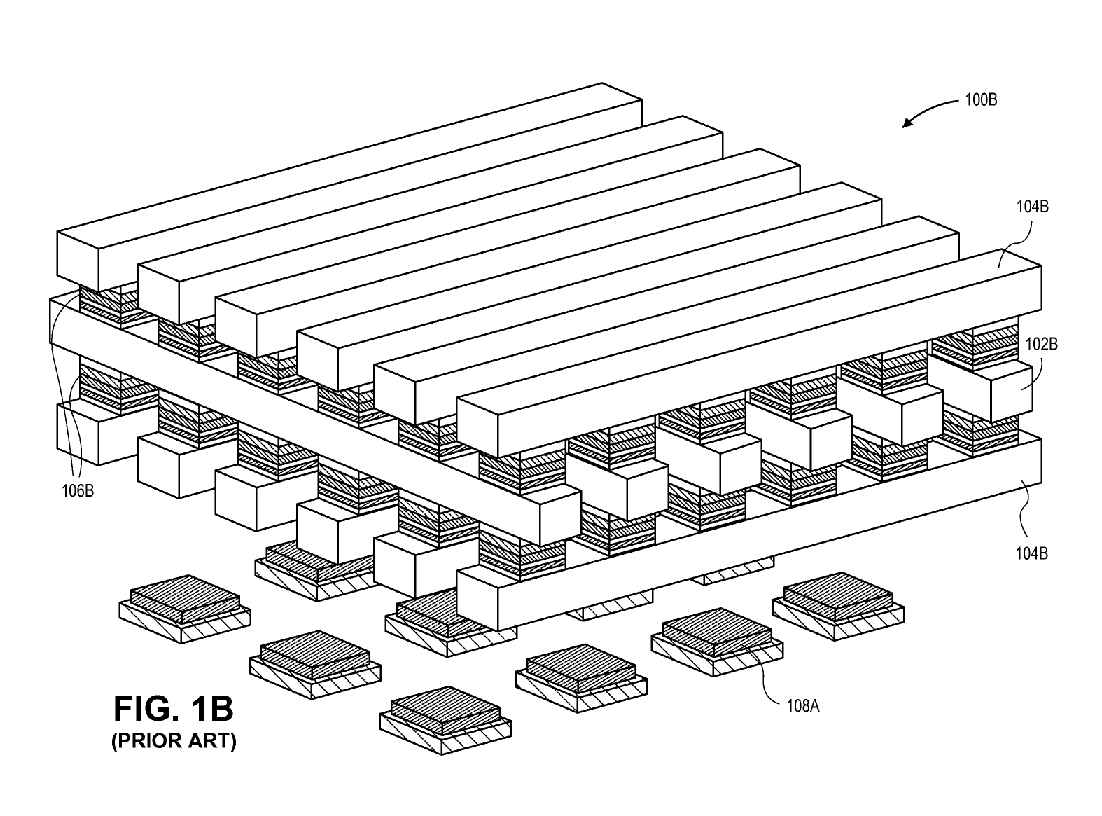

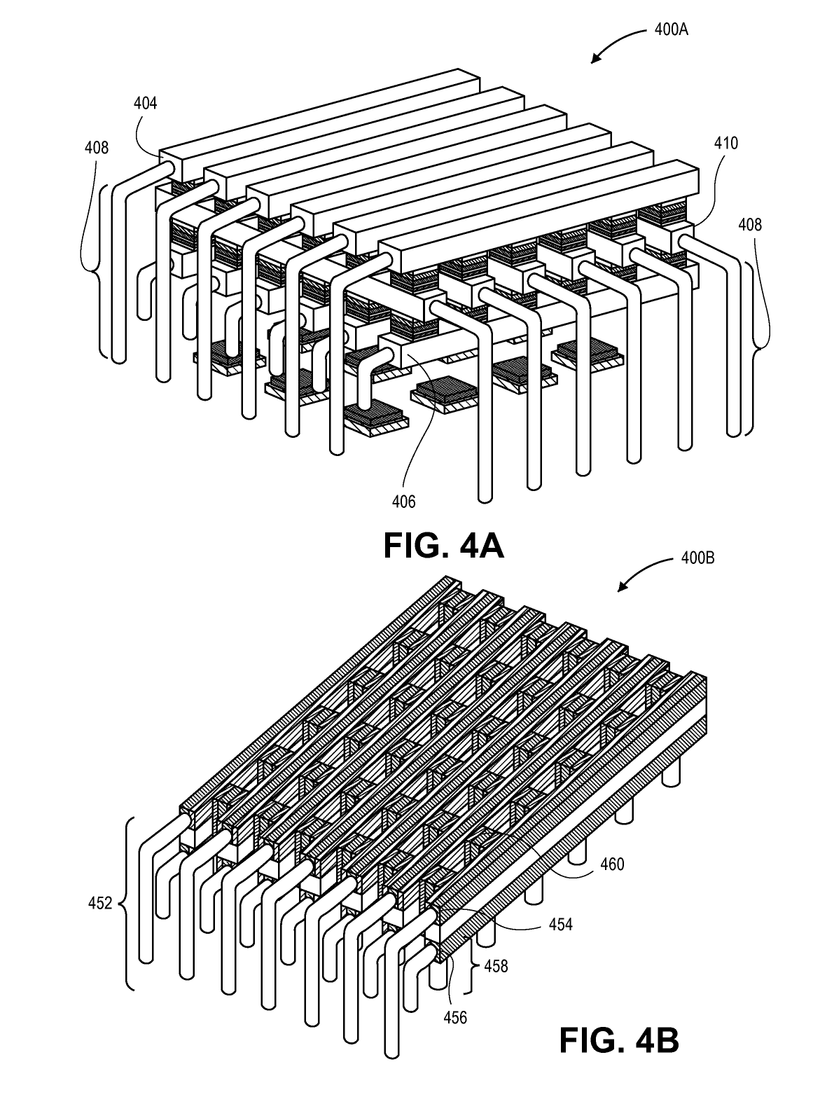

As a general overview, FIGS. 2A-2C illustrate angled three-dimensional views of key fabrication operations in a method of fabricating a vertical cross-point array with conductive oxide random access memory (CORAM) type memory elements, in accordance with an embodiment of the present invention. Referring to FIG. 2A, a material stack 200 includes a first metal layer 202, and oxide or nitride insulator layer 204, and a second metal layer 206. Referring to FIG. 2B, a first lithography and etch operation is used to form horizontal wordlines 208. Then (not shown), active oxide deposition, selector layer deposition and oxide fill processes are performed, as described in more detail in association with FIGS. 5A-5K below. Referring to FIG. 2C, a second lithography and etch operation is performed to form vias. The vias are filled with metal to form vertical bitlines 210. It is to be understood that the above described operations may be repeated to fabricate additionally layers including additional layers of memory elements.

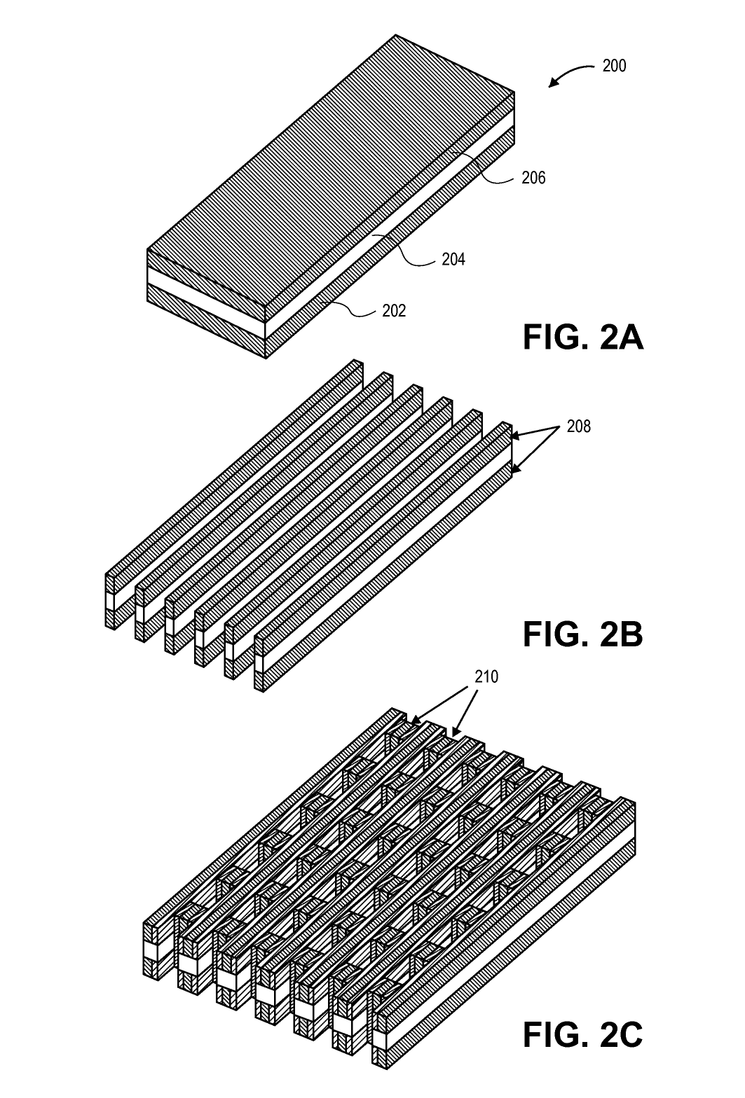

As an example of a resulting structure from the above fabrication approach, FIG. 3 illustrates an angled three-dimensional view of a vertical cross-point array with conductive oxide random access memory (CORAM) type memory elements, in accordance with an embodiment of the present invention. Referring to FIG. 3, a vertical CORAM cross-point array 300 is fabricated from a common (second) lithography and etch process to pattern vertical bitlines 302 for first and second layers of horizontal wordlines 304 and 306, respectively. Note that a first patterning step was used to pattern the two horizontal wordlines 304 and 306. Also shown are memory layer 308 and switch layer 310. In one embodiment, the memory layer 308 is a conductive oxide material layer, while the switch layer 310 is a non-conductive or insulating layer of, e.g., a non-conductive oxide material or a chalcogenide layer (e.g., a layer based on S²⁻, Se²⁻, or Te²⁻, etc.).

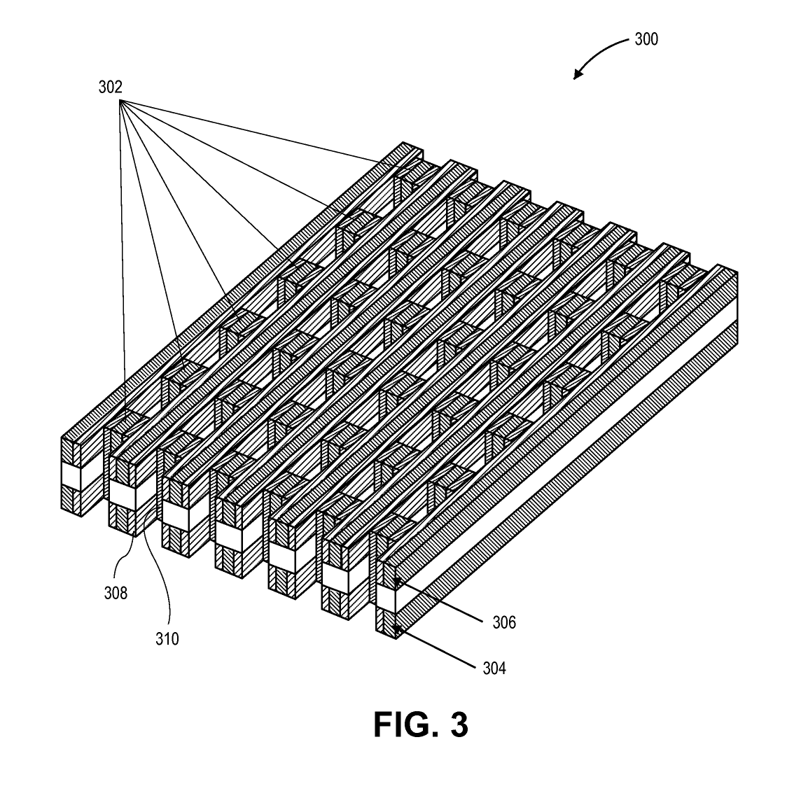

In an embodiment, advantages of a vertical cross-point array, such as array 300 of FIG. 3, with respect to the fabrication of embedded memory include an overall lower bitline resistance. A lower bitline resistance can result in lower needed operating voltage due to shorter bitlines. In one embodiment, shorter bitlines (and, hence, lower resistance bitlines) can be achieved in a vertical cross-point architecture since the bitlines do not need to be routed from each memory layer to an underlying silicon substrate. As an example, FIG. 4A illustrates an angled three-dimensional view of a conventional two-memory layer horizontally stacked cross-point memory array. Referring to FIG. 4A, an array 400A includes routing 402 for horizontal wordlines 404 and 406. Additional routing 408 is included for horizontal bitlines 410.

By contrast, in an embodiment, the bitlines can be formed to contact an underlying silicon substrate or layer directly. As an example, FIG. 4B illustrates an angled three-dimensional view of a vertical cross-point array with conductive oxide random access memory (CORAM) type memory elements, in accordance with an embodiment of the present invention. Referring to FIG. 4B, a vertical cross-point array 400B includes routing 452 for horizontal wordlines 454 and 456. However, contacts 458 for vertical bitlines 460 are formed directly to an underlying substrate (substrate not shown).

For a more detailed view of an approach to fabricating a vertical cross-point array such as array 300, FIGS. 5A-5K illustrate angled three-dimensional views of various fabrication operations in a method of fabricating a vertical cross-point array with conductive oxide random access memory (CORAM) type memory elements, in accordance with an embodiment of the present invention.

Referring to FIG. 5A, a material stack 500 includes a first metal layer 502, an oxide or nitride insulator layer 504, and a second metal layer 506. As shown in the cross-sectional view of FIG. 5A, a resist layer and/or hardmask layer 508 is formed and patterned on stack 500. An etch process may then be performed to etch at least a portion of the stack 500, as depicted in FIG. 5B. Referring to FIG. 5B, the metal layer 506 can, in an embodiment, be etched using an ICP/ECR plasma source and chemistry based on Cl₂/Ar. In one such embodiment, the metal etch is performed using a high power for verticality, followed by low power for more selectivity to oxide (e.g., selectivity to layer 504). The oxide or nitride insulator layer 504 can, in an embodiment, be etched using CₓF_{y} or CₓH_{y}F_{z}/Ar/O₂ chemistry for selectivity to top and bottom metal layers 502 and 504. It is noted that while O₂ may be desirable for selectivity to metal, O₂ can cause resist layer 508 to erode and, thus, the etch may be performed oxygen-free or with very little O₂. The metal layer 502 can, in one embodiment, be etched using the same etch as used for metal layer 506. Alternatively, metal layer 502 can, in another embodiment, be etched using a combination of CF₄/Cl₂ chemistry so as to not create too much selectivity to the middle insulator layer 504. The latter approach may be used to prevent unnecessary undercutting of the metal that is just above and just below the oxide (e.g., at locations 510). In a specific embodiment, a high power plasma is used for the final etching. The chemistry used for completing the etch of stack 500 can depend on the nature of the material directly below the metal layer 502 (shown in FIG. 5C). It is to be understood that stack 500 is shown as only partially etched in FIG. 5B, but that the etch is ultimately completed prior to next processing operations.

Referring to FIG. 5C, after completion of the etching of stack 500, an underlying substrate or material layer 512 is exposed. A conductive oxide (memory layer) 514 is formed, and a non-conducting selector layer 516 is formed conformal with the resulting structure. The conductive oxide layer 514 can be formed, in one embodiment, by consumption through oxidation of portion of metal layers 502 and 506, as depicted in FIG. 5C. However, in alternative embodiments, the conductive oxide layer 514 can be formed by non-selective deposition leaving a continuous film, or by selective deposition of a metal oxide material on exposed portions of metal layers 502 and 506 but not on insulator layer 504. In an embodiment, the non-conducting selector layer 516 is formed from a chalcogenide material, as described above, or from other insulating materials such as non-conductive oxides. In a specific embodiment, the non-conducting selector layer 516 is included to ultimately isolate one memory cell from another memory cell.

Referring to FIG. 5D, the selector layer 516 is etched to leave material remaining only on the sidewalls of the structure of FIG. 5C. A metal layer 518 is then deposited on the structure of FIG. 5D, as depicted in FIG. 5E. Referring to FIG. 5F, the metal layer 518 is planarized, e.g., by chemical mechanical polishing, to re-expose the uppermost layers of the structure of FIG. 5D. A lithography process is then performed to provide a patterned resist or hardmask 520 above the structure of FIG. 5F, as depicted in FIG. 5G. In one embodiment, the lithography patterning of FIG. 5G is performed orthogonally to the direction of lithography patterning of FIG. 5A. Referring to FIG. 5H, the structure of FIG. 5G is etched using the patterned resist or hardmask 520 as mask to expose portions of underlying substrate or material layer 512. In one such embodiment, the metal layer 518 is etched selective to exposed insulating layers, e.g., is etched using a plasma based on Cl₂, HBr, Ar. It is noted that since the etch process is a subtractive metal etch process, care may need to be taken to remove stringers off of the sidewalls, e.g., by using a delicate over-etch process.

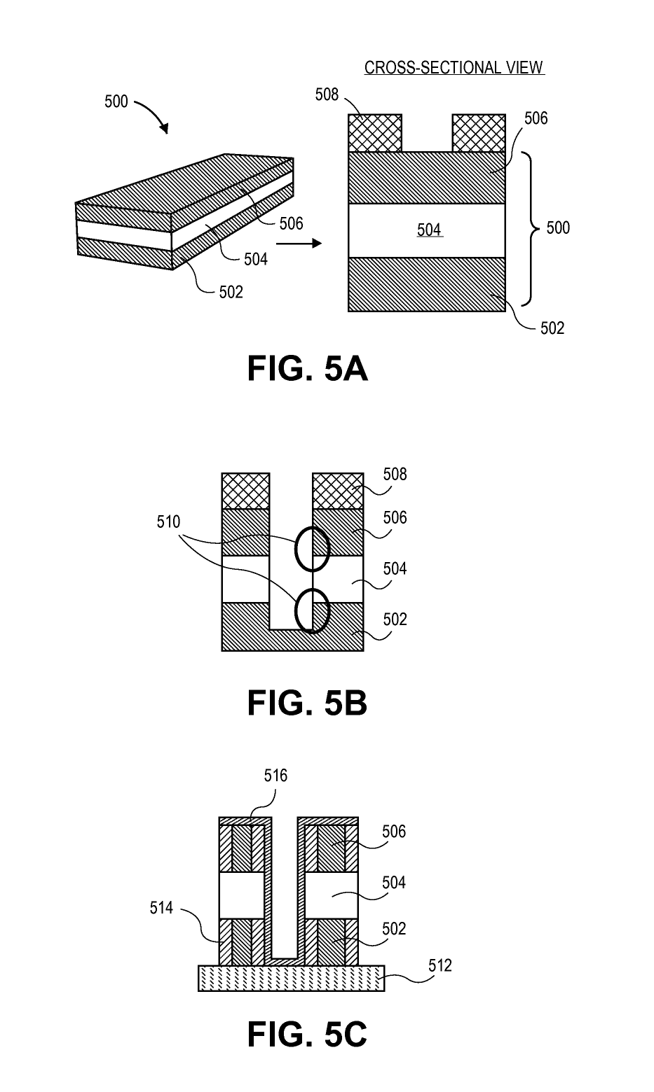

Referring to FIG. 5I, the patterned resist or hardmask 520 is removed to expose patterned metal layer 518. A dielectric layer 522 is then formed on the structure of FIG. 5I, as depicted in FIG. 5J. Referring to FIG. 5K, the dielectric layer 522 is planarized, e.g., by chemical mechanical polishing, to provide a vertical cross-point array with isolated memory elements. FIG. 5K includes a top view and cross-sectional view (1) taken through the dielectric layer 522 and cross-sectional view (2) taken through metal layer 518. To aid with illustration, FIG. 6 illustrates a portion 600 of a vertical cross-point array showing the key features of a horizontal wordline (WL), a vertical bitline (BL), and a memory/selector device at a cross-point of the horizontal wordline (WL) and the vertical bitline (BL), in accordance with an embodiment of the present invention. Referring to FIG. 6, there are thus provided active layers of selector and memory elements at each x-section of vertical bitline and horizontal wordline.

Features of embodiments herein may be detectable by physical analysis. For example, a scanning electron microscope (SEM) may be used to determine if bitlines are vertical and that both thin film selector and thin film memory elements are located at the cross-sections of vertical bitlines and horizontal wordline. A transmission electron microscope (TEM) may be used to determine if an isolated thin film selector and thin film memory element are located at the cross-sections of vertical bitlines and horizontal wordlines. One of the differences of one or more embodiments described herein with respect to state of the art resistive devices is that all layers in the stack of the memory element are composed of conducting thin films. As a result, the device structure for the resulting resistive memory element is different from the state of the art devices where at least one of the films is an insulator and/or dielectric film. For such films in the conventional devices, the resistivity is many orders of magnitude higher than that of metals or metal compounds and is essentially non measurable at low field until the device is formed. However, in embodiments described herein, since all layers in the memory element are conductors, the arrangement enables one or more of the following: (1) low voltage operation, e.g., less than 1 Volt operation; (2) elimination of the need for a one time high voltage, commonly called forming voltage, required for state of the art RRAM; and (3) low resistances (e.g., since all components are conductors) which can provide for fast read in operation of a memory device having the MCOM structure.

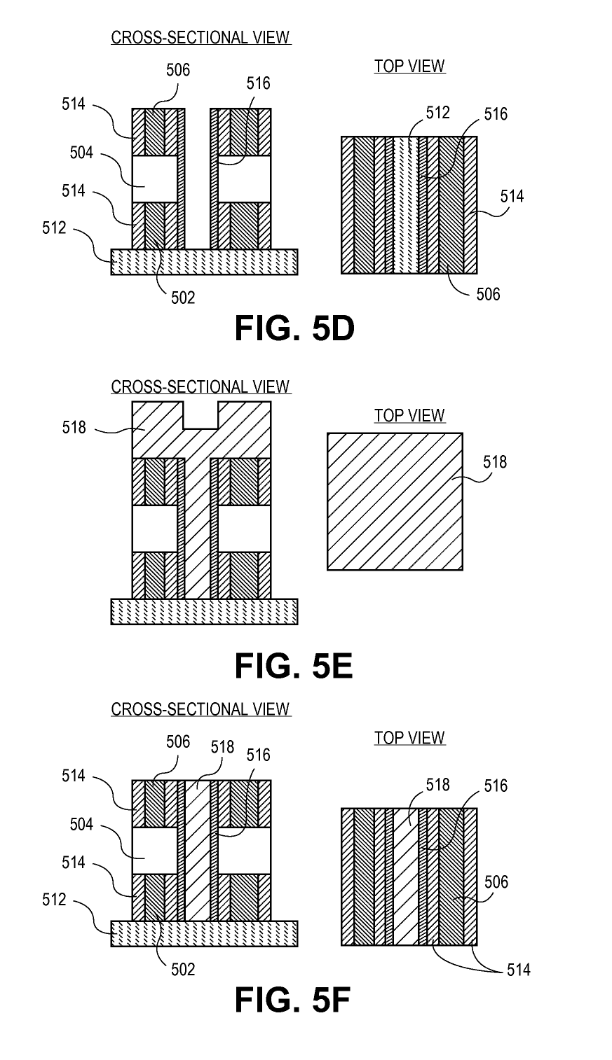

In an aspect, the individual memory elements of the above described vertical cross-point arrays may be anionic-based conductive oxide memory elements. For example, FIG. 7 illustrates an operational schematic representing a changing of states for an anionic-based metal-conductive oxide-metal (MCOM) memory element, in accordance with an embodiment of the present invention. Referring to FIG. 7, a memory element 700 includes an electrode/conductive oxide/electrode material stack. The memory element 700 may begin in a less conductive state (1), with the conductive oxide layer being in a less conductive state 704A. An electrical pulse, such as a duration of a positive bias (2) may be applied to provide memory element 700 in a more conductive state (3), with the conductive oxide layer being in a more conductive state 704B. An electrical pulse, such as a duration of a negative bias (4) may be applied to again provide memory element 700 having the less conductive state (1). Thus, electrical pulsing may be used to change resistance of the memory element 700.

As such, in an embodiment, a memory element includes an anionic-based conductive oxide layer sandwiched between two electrodes. Resistivity of the conductive oxide layer in low field (when device is read) is, in some embodiments, in the range found typical of conductive films of metal compounds, e.g. TiAlN. For example, in a specific embodiment, the resistivity for such a layer is approximately in the range of 0.1 Ohm cm-10 kOhm cm when measured at low field. Resistivity of the film is tuned depending in the memory element size to achieve final resistance value in the range compatible with fast read. Resistivity of the conductive oxide layer in high field (when device is written to) is, in some embodiments, in the range found typical of conductive films of metals, like Ti, as conduction in this regime has both high electronic and ionic current components. For example, in a specific embodiment, the resistivity for such a layer is approximately in the range of 10 u Ohm·cm-1 mOhm·cm in high field (measured for the specific thickness used in the stack). Composition of the conductive oxide layer may be tuned in such a way that a small change in its composition results in a large change in resistance. Resistance change occurs, in some embodiments, due to a Mott transition, e.g., when injected/extracted charge causes phase transition in the conductive oxide layer between more and less resistive phase configurations. In other embodiments, the resistance change can be induced by changing the concentration of oxygen vacancies in the conductive oxide layer.

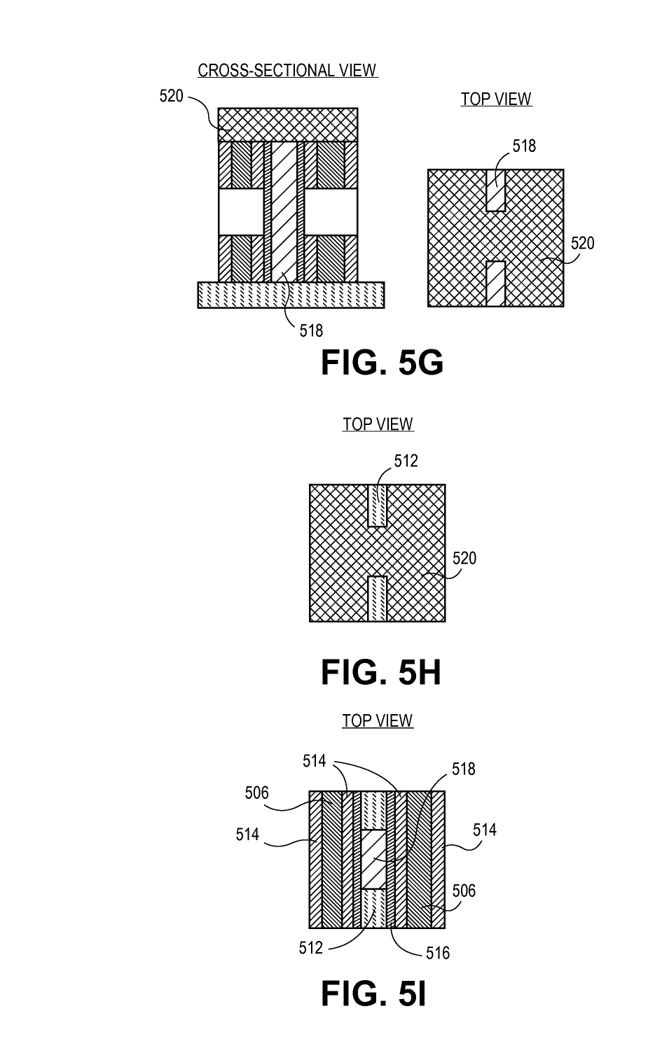

As an example of one approach, FIG. 8 illustrates a schematic representation of resistance change in an anionic-based conductive oxide layer induced by changing the concentration of oxygen vacancies in the conductive oxide layer, in accordance with an embodiment of the present invention. Referring to FIG. 8, a memory element 800 is shown as deposited (A). The memory element includes a conductive oxide layer 804 between a palladium (Pd) electrode 802 and a tungsten (W) electrode 806. Oxygen atoms and oxygen vacancies may be distributed as shown in (A). Referring to (B) of FIG. 8, upon application of a positive bias, the memory element 800 can be made more conductive. In that state, oxygen atoms migrate to the electrode 806, while vacancies remain throughout the layer 804. Referring to (C) of FIG. 8, upon application of a negative bias, the memory element can be made less conductive. That that state, oxygen atoms are distributed more evenly throughout layer 804. Accordingly, in an embodiment, effective composition (e.g., the location of oxygen atoms versus vacancies) of a conductive oxide layer is modified to change resistance of a memory element. In a specific embodiment, an applied electrical field, which drives such compositional change, is tuned to values approximately in the range of 1e6-1e7 V/cm.

As mentioned briefly above, in an embodiment, one electrode in a memory element including an anionic-based conductive oxide layer is a noble metal based electrode, while the other electrode in is a transition metal for which some of the lower valence oxides are conductive (e.g., to act as an oxygen reservoir). That is, when oxygen atoms migrate to the transition metal oxide, the resulting interfacial transition metal oxide formed remains conductive. Examples of suitable transition metals which form conductive oxides include but are not limited to, W, V, Cr, or Ir. In other embodiments, one or both of the electrodes is fabricated from an electro-chromic material. In other embodiments, one or both of the electrodes is fabricated from a second, different conductive oxide material. In an embodiment, examples of suitable conductive oxides include, but are not limited to: TTO (In₂O₃₋ₓSnO₂₋ₓ), In₂O₃₋ₓ, sub-stoichiometric yttria doped zirconia (Y₂O₃₋ₓZrO₂₋ₓ), or La₁₋ₓSrₓGa_{1-y}Mg_{y}O_{3-X-0.5(x+y)}. In another embodiment, the conductive oxide layer is composed of a material with two or more metal elements (e.g., as contrasted to common RRAM memories using one metal such as found in binary oxides, such as HfOₓ or TaOₓ). In such ternary, quaternary, etc. alloys, the metals used are from adjacent columns of the periodic table. Specific examples of suitable such conductive oxides include, but are not limited to: Y and Zr in Y₂O₃₋ₓZrO₂₋ₓ, In and Sn in In₂O₃₋ₓSnO₂₋ₓ, or Sr and La in La₁₋ₓSrₓGa_{1-y}Mg_{y}O₃. Such materials may be viewed as compositions selected to have aliovalent substitution to significantly increase the number of oxygen vacancies. Note, that in some embodiments the change of resistance of such electrode during programming can contribute to the total resistance change.

In an embodiment, examples of suitable noble metals include, but are not limited to Pd or Pt. In a specific embodiment, a more complex, yet still all-conductive, stack includes an approximately 10 nm Pd first electrode layer, an approximately 3 nm In₂O₃₋ₓ and/or SnO₂₋ₓ conductive oxide layer, and a second electrode stack composed of approximately 20 nm tungsten/10 nm Pd/100 nm TiN/55 nm W.

In another aspect, one or more embodiments include fabrication of a memory stack having a conductive oxide layer based on cationic conductivity versus an oxide-based resistive change memories where programming is driven by anionic conductivity through oxygen vacancy generation. By basing a memory element on a cationic-based conductive oxide, instead of an anionic-based conductive oxide, faster programming operations may be achieved. Such increase in performance may be based, at least partly, on the observation that ionic conductivities are much higher for cationic conductive oxides versus anionic conductive oxides, e.g., the ionic conductivity for lithium silicate (Li₄SiO₄, a cationic-based oxide) is greater that that of zirconia (ZrO₂ or ZrOₓ, an anionic-based oxide.

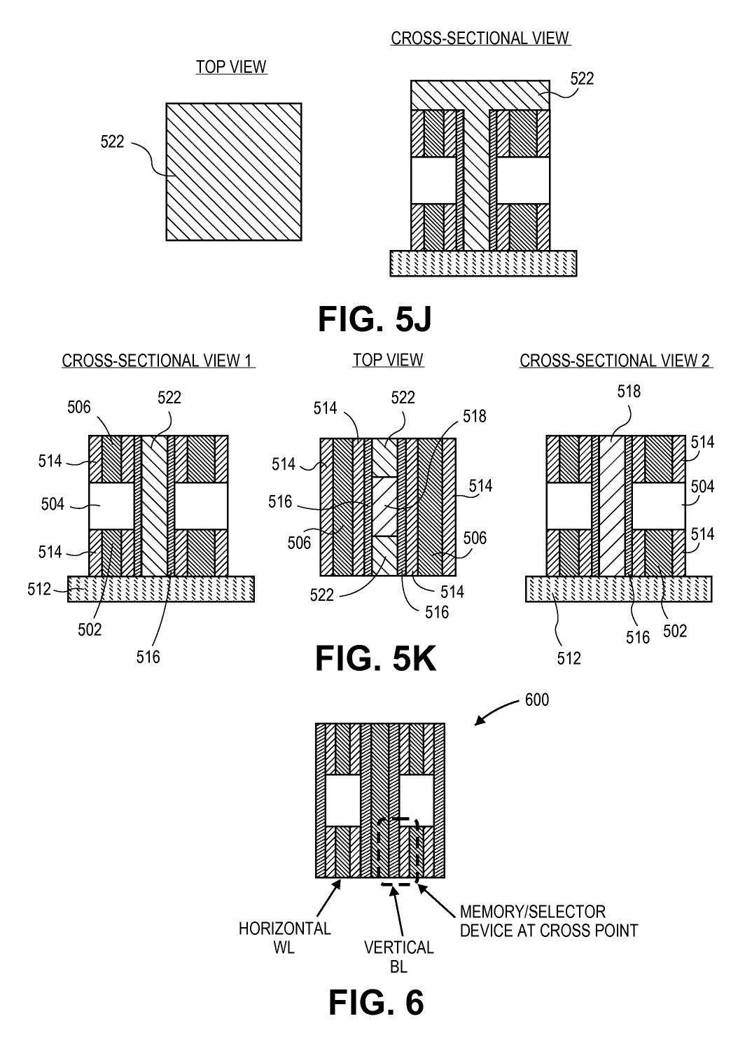

As an example, FIG. 9 illustrates an operational schematic representing a changing of states for a cationic-based metal-conductive oxide-metal (MCOM) memory element, in accordance with an embodiment of the present invention. Referring to FIG. 9, memory element 900 may begin in a more conductive state (1), with a cationic-based conductive oxide layer being in a more conductive state 904A. An electrical pulse, such as a duration of a positive bias (2) may be applied to provide memory element 900 in a less conductive state (3), with the cationic-based conductive oxide layer being in a less conductive state 904B. An electrical pulse, such as a duration of a negative bias (4) may be applied to again provide memory element 900 having the more conductive state (1). Thus, electrical pulsing may be used to change resistance of the memory element 900. Polarity applied is such as to attract active cations of in the memory layer to the intercalation electrode under negative bias.

As such, in an embodiment, a memory element includes a cationic-based conductive oxide layer sandwiched between two electrodes. Resistivity of the cationic-based conductive oxide layer in low field (when device is read) is, in some embodiments, can be as low as found typical of conductive films of metal compounds, e.g. TiAlN. For example, in a specific embodiment, the resistivity for such a layer is approximately in the range of 0.1 Ohm cm-10 kOhm cm when measured at low field (measured for the specific thickness used in the stack). Resistivity of the film is tuned depending in the memory element size to achieve final resistance value in the range compatible with fast read.

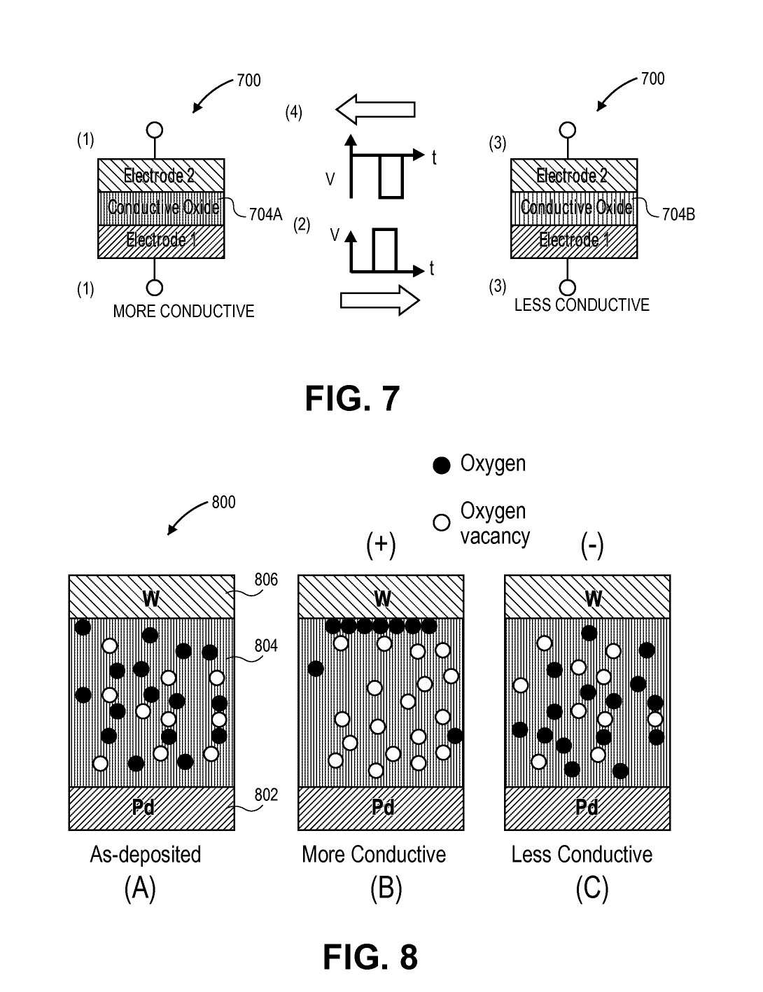

As an example of one approach, FIG. 10 illustrates a schematic representation of resistance change in a cationic-based conductive oxide layer induced by changing the concentration of cation vacancies (such as lithium cation vacancies) in the conductive oxide layer, in accordance with an embodiment of the present invention.

Referring to FIG. 10, a memory element 1000 is shown as deposited (A). The memory element includes a cationic-based conductive oxide layer 1004 between a bottom electrode 1002 and a top electrode 1006. In a specific example, the layer 1004 is a lithium cobalt oxide layer, described in greater details below, and lithium atoms and lithium vacancies are distributed as shown in (A). Referring to (B) of FIG. 10, upon application of a negative bias, the memory element 1000 can be made more conductive. In that state, lithium atoms migrate to the top electrode 1006, while vacancies remain throughout the layer 1004. Referring to (C) of FIG. 10, upon application of a positive bias to one of the electrodes, the memory element can be made less conductive. In that state, lithium atoms are distributed more evenly throughout layer 1004. Accordingly, in an embodiment, effective composition (e.g., the location of lithium atoms (or cations) versus vacancies) of a cationic-based conductive oxide layer is modified to change resistance of a memory element, in some embodiments due to stoichiometry—induced Mott transition. In a specific embodiment, an applied electrical field, which drives such compositional change during write operation, is tuned to values approximately in the range of 1e6-1e7 V/cm.

In an embodiment, referring again to FIG. 10, the cationic-based conductive oxide layer 1004 is composed of a material suitable for cation-based mobility within the layer itself. In a specific exemplary embodiment, layer 1004 of FIG. 10 part (A) is composed of lithium cobalt oxide (LiCoO₂). Then, in part (B), the corresponding layer becomes lithium deficient (e.g., L_{<0.75}CoO₂) when a negative bias is applied and lithium atoms (e.g., as cations) migrate toward electrode 1006. By contrast, in part (C), the corresponding layer becomes lithium rich (e.g., Li_{>0.95}CoO₂) when a positive bias is applied and lithium atoms (e.g., as cations) migrate away from electrode 1006. In other embodiments, other suitable compositions with cationic conductivity include, but are not limited to, LiMnO₂, Li₄TiO₁₂, LiNiO₂, LiNbO₃, Li₃N:H, LiTiS₂ (all of which are lithium atom or Li⁺ mobility based), Na β-alumina (which is sodium atom or Na⁺ mobility based), or AgI, RbAg₄I₅, AgGeAsS₃ (all of which are silver atom or Ag⁺ mobility based). In general, these examples provide materials based on cation mobility or migration, which is typically much faster than anionic-based mobility or migration (e.g., for oxygen atoms or O²⁻ anions).

In an embodiment, referring again to FIG. 10, one electrode (e.g., bottom electrode 1002) in a memory element including a cationic conductive oxide layer is a noble metal based electrode. In one embodiment, examples of suitable noble metals include, but are not limited to palladium (Pd) or platinum (Pt). In a specific embodiment, a memory stack includes a bottom electrode composed of an approximately 10 nanometer thick Pd layer. It is to be understood that use of the terms “bottom” and “top” for electrodes 1002 and 1006 need only be relative and are not necessarily absolute with respect to, e.g., an underlying substrate.

In an embodiment, referring again to FIG. 10, the other electrode (e.g., top electrode 1006) in a memory element including a cationic conductive oxide layer is an “intercalation host” for migrating cations. The material of the top electrode is a host in a sense that the material is conductive with or without the presence of the migrating cations and is not substantially altered in the absence or presence of the migrating cations. In an exemplary embodiment, the top electrode is composed of a material such as, but not limited to, graphite, or metal chalcogenides such as disulfides (e.g., TaS₂). Such materials are conductive as well as absorbing of cations such as Li⁺. This is in contrast to an electrode for an anionic based conductive oxide which may include a metal with a corresponding conductive oxide to accommodate migrating oxygen atoms or anions.

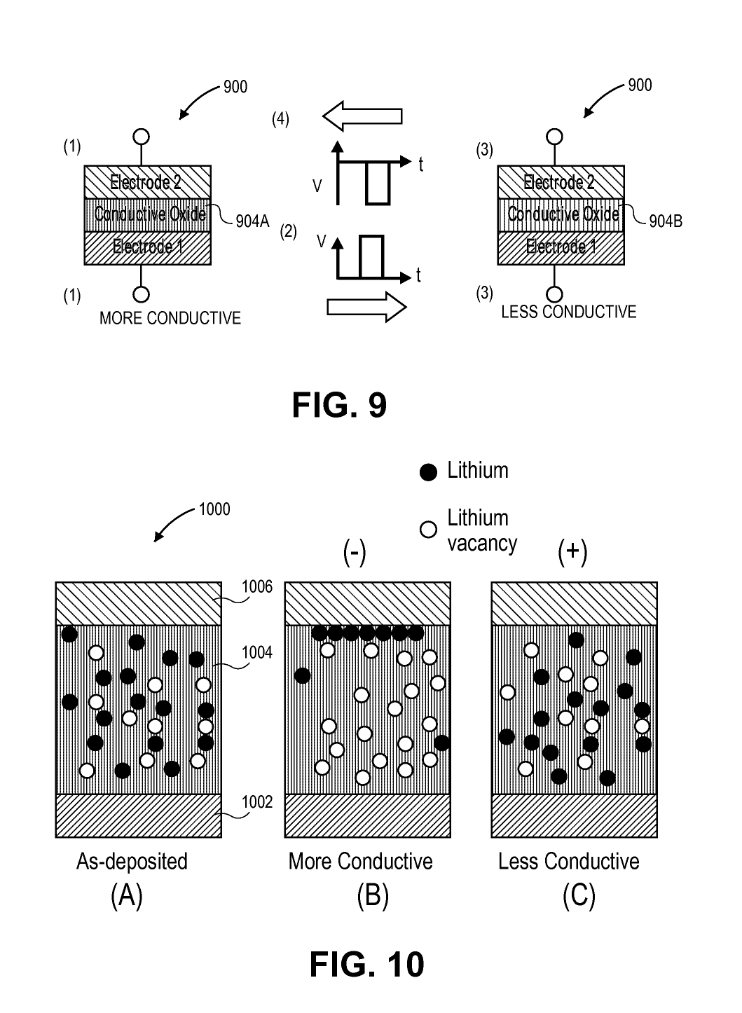

Referring again to the description associated with FIGS. 7-10 above, a stack of conductive layers including a conductive metal oxide layer may be used to fabricate as memory bit cell. For example, FIG. 11 illustrates a schematic of a memory bit cell 1100 which includes a metal-conductive oxide-metal (MCOM) memory element 1110, in accordance with an embodiment of the present invention.

Referring to FIG. 11, the MCOM memory element 1110 may include a first conductive electrode 1112 with a conductive metal oxide layer 1114 adjacent the first conductive electrode 1112. A second conductive electrode 1116 is adjacent the conductive metal oxide layer 1114. The second conductive electrode 1116 may be electrically connected to a bit line 1132. The first conductive electrode 1112 may be coupled with a transistor 1134. The transistor 1134 may be coupled with a wordline 1136 and a source line 1138 in a manner that will be understood to those skilled in the art. The memory bit cell 1100 may further include additional read and write circuitry (not shown), a sense amplifier (not shown), a bit line reference (not shown), and the like, as will be understood by those skilled in the art, for the operation of the memory bit cell 1100. It is to be understood that a plurality of the memory bit cells 1100 may be operably connected to one another to form a memory array (e.g., as shown in, and described in association with, FIGS. 3, 4A and 4B), wherein the memory array can be incorporated into a non-volatile memory device. It is to be understood that the transistor 1134 may be connected to the second conductive electrode 1116 or the first conductive electrode 1112, although only the latter is shown.

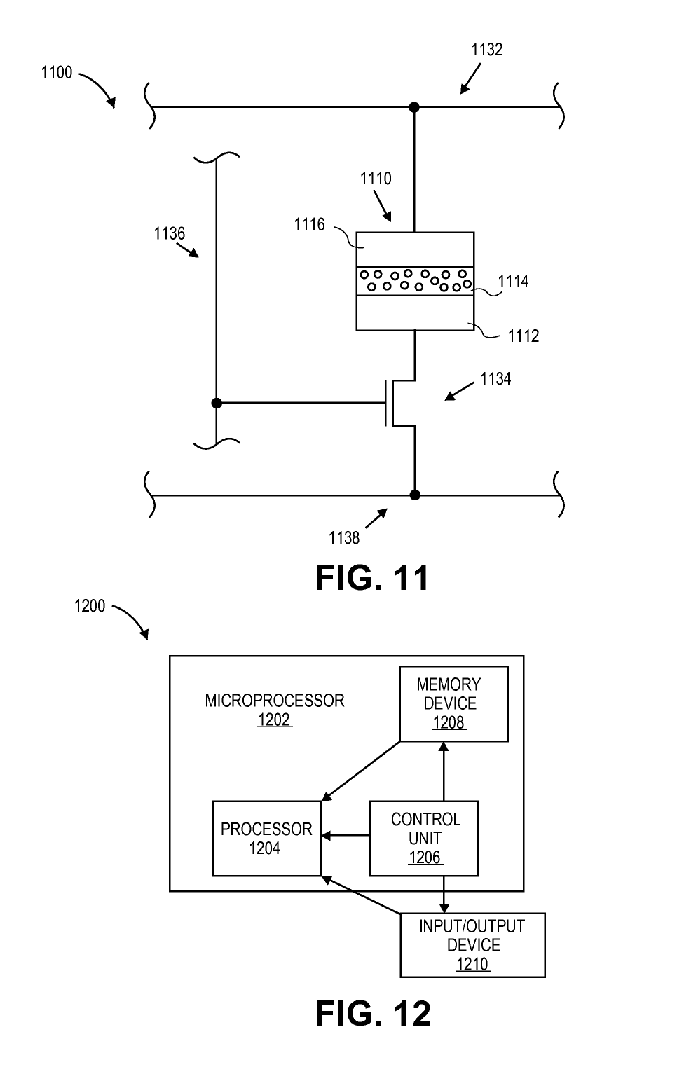

FIG. 12 illustrates a block diagram of an electronic system 1200, in accordance with an embodiment of the present invention. The electronic system 1200 can correspond to, for example, a portable system, a computer system, a process control system, or any other system that utilizes a processor and an associated memory. The electronic system 1200 may include a microprocessor 1202 (having a processor 1204 and control unit 1206), a memory device 1208, and an input/output device 1210 (it is to be understood that the electronic system 1200 may have a plurality of processors, control units, memory device units and/or input/output devices in various embodiments). In one embodiment, the electronic system 1200 has a set of instructions that define operations which are to be performed on data by the processor 804, as well as, other transactions between the processor 1204, the memory device 1208, and the input/output device 1210. The control unit 1206 coordinates the operations of the processor 1204, the memory device 1208 and the input/output device 1210 by cycling through a set of operations that cause instructions to be retrieved from the memory device 1208 and executed. The memory device 1208 can include a memory element having a conductive oxide and electrode stack as described in the present description. In an embodiment, the memory device 1208 is embedded in the microprocessor 1202, as depicted in FIG. 12.

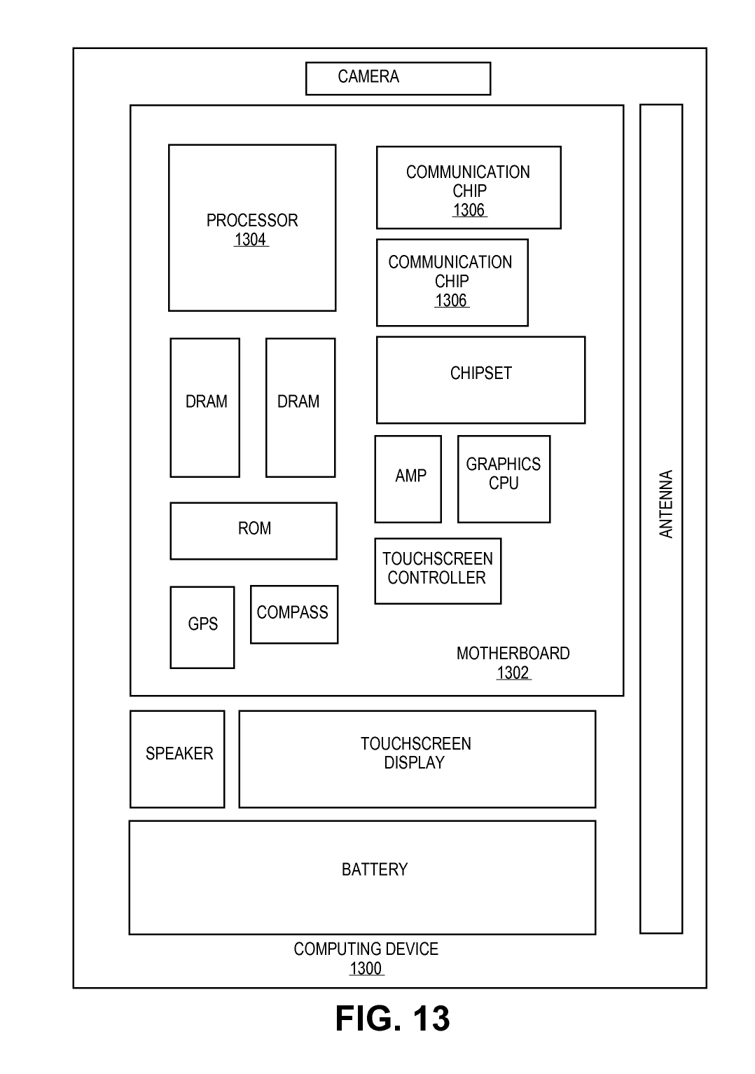

FIG. 13 illustrates a computing device 1300 in accordance with one implementation of the invention. The computing device 1300 houses a board 1302. The board 1302 may include a number of components, including but not limited to a processor 1304 and at least one communication chip 1306. The processor 1304 is physically and electrically coupled to the board 1302. In some implementations the at least one communication chip 1306 is also physically and electrically coupled to the board 1302. In further implementations, the communication chip 1306 is part of the processor 1304.

Depending on its applications, computing device 1300 may include other components that may or may not be physically and electrically coupled to the board 1302. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 1306 enables wireless communications for the transfer of data to and from the computing device 1300. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1306 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 1300 may include a plurality of communication chips 1306. For instance, a first communication chip 1306 may be dedicated to shorter range wireless communications such as Wi-Fi and Bluetooth and a second communication chip 1306 may be dedicated to longer range wireless communications such as GPS, EDGE, GPRS, CDMA, WiMAX, LTE, Ev-DO, and others.

The processor 1304 of the computing device 1300 includes an integrated circuit die packaged within the processor 1304. In some implementations of the invention, the integrated circuit die of the processor includes, or is electrically coupled with, one or more devices low voltage embedded memory having conductive oxide and electrode stacks in accordance with implementations of the invention. The term “processor” may refer to any device or portion of a device that processes electronic data from registers and/or memory to transform that electronic data into other electronic data that may be stored in registers and/or memory.

The communication chip 1306 also includes an integrated circuit die packaged within the communication chip 1306. In accordance with another implementation of the invention, the integrated circuit die of the communication chip includes, or is electrically coupled with, one or more devices low voltage embedded memory having conductive oxide and electrode stacks in accordance with implementations of the invention.

In further implementations, another component housed within the computing device 1300 may contain an integrated circuit die that includes, or is electrically coupled with, one or more devices low voltage embedded memory having conductive oxide and electrode stacks in accordance with implementations of the invention.

In various implementations, the computing device 1300 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 1300 may be any other electronic device that processes data.

Accordingly, one or more embodiments of the present invention relate generally to the fabrication of microelectronic memory. The microelectronic memory may be non-volatile, wherein the memory can retain stored information even when not powered. One or more embodiments of the present invention relate to the fabrication of a memory element having a conductive oxide and electrode stack for non-volatile microelectronic memory devices. Such an element may be used in an embedded non-volatile memory, either for its non-volatility, or as a replacement for embedded dynamic random access memory (eDRAM). For example, such an element may be used for, or in place of, 1T-1X memory (X=capacitor or resistor) at competitive cell sizes within a given technology node.

In an embodiment, an array memory element including a conductive oxide layer is fabricated by a process flow including a capacitor flow for which all active layers are deposited in situ to eliminate contamination related effects. Memory operation can be performed at voltages at or below DC 1V. In one embodiment, the fabricated devices do not require application of initial high voltage DC sweep, e.g., as is known as first fire for conventional devices.

Thus, embodiments of the present invention include vertical cross-point embedded memory architectures for metal-conductive oxide-metal (MCOM) memory elements.

In an embodiment, a memory array includes a substrate. A plurality of horizontal wordlines is disposed in a plane above the substrate. A plurality of vertical bitlines is disposed above the substrate and interposed with the plurality of horizontal wordlines to provide a plurality of cross-points between ones of the plurality of horizontal wordlines and ones of the plurality of vertical bitlines. A plurality of memory elements is disposed in the plane above the substrate, one memory element disposed at each cross-point between the corresponding wordline and bitline of the cross-point.

In one embodiment, each of the plurality of memory elements is a conductive-oxide random access memory (CORAM) element.

In one embodiment, the CORAM element includes an anionic-based conductive oxide memory layer.

In one embodiment, the anionic-based conductive oxide memory layer is composed of an oxygen vacancy doped low resistance oxide layer having a thickness approximately in the range of 1-10 nanometers.

In one embodiment, the anionic-based conductive oxide memory layer is composed of a material such as, but not limited to, ITO (In₂O₃₋ₓSnO₂₋ₓ), In₂O₃₋ₓ, sub-stoichiometric yttria doped zirconia (Y₂O₃₋ₓZrO₂₋ₓ), or La₁₋ₓSrₓGa_{1-y}Mg_{y}O_{3-X-0.5(x+y)}.

In one embodiment, the resistivity of the anionic-based conductive oxide memory layer is approximately in the range of 10 mOhm cm-10 kOhm when measured at a low field of approximately 0.1V.

In one embodiment, the anionic-based conductive oxide memory layer is coupled to an electrode that provides an oxygen reservoir.

In one embodiment, the CORAM element includes a cationic-based conductive oxide memory layer.

In one embodiment, the cationic-based conductive oxide memory layer has lithium (Li⁺) mobility and is a layer such as, but not limited to, a LiCoO₂, LiMnO₂, Li₄TiO₁₂, LiNiO₂, LiNbO₃, Li₃N:H or LiTiS₂ layer.

In one embodiment, the cationic-based conductive oxide memory layer has sodium (Na⁺) mobility and is a layer of Na β-alumina.

In one embodiment, the cationic-based conductive oxide memory layer has silver (Ag⁺) mobility and is a layer such as, but not limited to, a AgI, RbAg₄I₅ or AgGeAsS₃ layer.

In one embodiment, the resistivity of the cationic-based conductive oxide memory layer is approximately in the range of 10 mOhm cm-10 kOhm when measured at a low field of approximately 0.1V.

In one embodiment, the cationic-based conductive oxide memory layer is coupled to an electrode that is an intercalation host for cations.

In one embodiment, the memory array further includes a selector layer disposed at each cross-point between the corresponding bitline and memory element.

In one embodiment, the memory array further includes a plurality of switch transistors for the array, the switch transistors disposed above the substrate and below the plurality of horizontal wordlines, the plurality of vertical bitlines, and the plurality of memory elements.

In one embodiment, the plurality of vertical bitlines is coupled to the underlying substrate without additional routing layers.

In one embodiment, the memory array further includes a second plurality of horizontal wordlines disposed in a second plane above and parallel with the first plane. The plurality of vertical bitlines is also interposed with the second plurality of horizontal wordlines to provide a second plurality of cross-points between ones of the second plurality of horizontal wordlines and ones of the plurality of vertical bitlines. The memory array also further includes a second plurality of memory elements disposed in the second plane, one memory element disposed at each cross-point between the corresponding wordline and bitline of the cross-point.

In an embodiment, a conductive-oxide random access memory (CORAM) array includes a plurality of cross-points in a horizontal plane above a substrate, each cross-point formed from a corresponding horizontal wordline and vertical bitline. The CORAM array also includes a plurality of CORAM elements, each CORAM element disposed at a corresponding one cross-point.

In one embodiment, each of the plurality of CORAM elements includes an anionic-based conductive oxide memory layer.

In one embodiment, each of the plurality of CORAM elements includes a cationic-based conductive oxide memory layer.

In one embodiment, the CORAM array further includes a second plurality of cross-points in a second horizontal plane above the first horizontal plane, each cross-point formed from a corresponding horizontal wordline and vertical bitline. The CORAM array also further includes a second plurality of CORAM elements, each CORAM element disposed at a corresponding one cross-point of the second plurality of cross-points. A same bitline couples one CORAM element of the first plurality of CORAM elements and one CORAM element of the second plurality of CORAM elements.

In an embodiment, a method of fabricating a memory array includes performing a first single lithographic operation to form two or more pluralities of horizontal wordlines, each plurality of horizontal wordlines disposed in a different plane above a substrate. The method also includes performing a second single lithographic operation to form a plurality of vertical bitlines, each bitline forming a cross-point with a corresponding one of each of the two or more pluralities of horizontal wordlines. The method also includes forming a memory element at each cross-point.

In one embodiment, forming the memory element at each cross-point includes forming a conductive-oxide random access memory (CORAM) element.

In one embodiment, forming the CORAM element includes forming an anionic-based conductive oxide memory layer.

In one embodiment, forming the CORAM element includes forming a cationic-based conductive oxide memory layer.

1. A memory array, comprising:
a substrate;
a plurality of horizontal wordlines disposed in a plane above the substrate;
a plurality of vertical bitlines disposed above the substrate and interposed with the plurality of horizontal wordlines to provide a plurality of cross-points between ones of the plurality of horizontal wordlines and ones of the plurality of vertical bitlines;
a plurality of memory elements disposed in the plane above the substrate, one memory element disposed at each cross-point between the corresponding wordline and bitline of the cross-point.

2. The memory array of claim 1, wherein each of the plurality of memory elements is a conductive-oxide random access memory (CORAM) element.

3. The memory array of claim 2, wherein the CORAM element includes an anionic-based conductive oxide memory layer.

4. The memory array of claim 3, wherein the anionic-based conductive oxide memory layer comprises an oxygen vacancy doped low resistance oxide layer having a thickness approximately in the range of 1-10 nanometers.

5. The memory array of claim 3, wherein the anionic-based conductive oxide memory layer comprises a material selected from the group consisting of ITO (In₂O₃₋ₓSnO₂₋ₓ), In₂O₃₋ₓ, sub-stoichiometric yttria doped zirconia (Y₂O₃₋ₓZrO₂₋ₓ), and La₁₋ₓSrₓGa_{1-y}Mg_{y}O_{3-X-0.5(x+y)}.

6. The memory array of claim 3, wherein the resistivity of the anionic-based conductive oxide memory layer is approximately in the range of 10 mOhm cm-10 kOhm when measured at a low field of approximately 0.1V.

7. The memory array of claim 3, wherein the anionic-based conductive oxide memory layer is coupled to an electrode that provides an oxygen reservoir.

8. The memory array of claim 2, wherein the CORAM element includes a cationic-based conductive oxide memory layer.

9. The memory array of claim 8, wherein the cationic-based conductive oxide memory layer has lithium (Li⁺) mobility and is selected from the group consisting of LiCoO₂, LiMnO₂, Li₄TiO₁₂, LiNiO₂, LiNbO₃, Li₃N:H and LiTiS₂.

10. The memory array of claim 8, wherein the cationic-based conductive oxide memory layer has sodium (Na⁺) mobility and is Na □-alumina.

11. The memory array of claim 8, wherein the cationic-based conductive oxide memory layer has silver (Ag⁺) mobility and is selected from the group consisting of AgI, RbAg₄I₅ and AgGeAsS₃.

12. The memory array of claim 8, wherein the resistivity of the cationic-based conductive oxide memory layer is approximately in the range of 10 mOhm cm-10 kOhm when measured at a low field of approximately 0.1V.

13. The memory array of claim 8, wherein the cationic-based conductive oxide memory layer is coupled to an electrode that is an intercalation host for cations.

14. The memory array of claim 1, further comprising:
a selector layer disposed at each cross-point between the corresponding bitline and memory element.

15. The memory array of claim 1, further comprising:
a plurality of switch transistors for the array, the switch transistors disposed above the substrate and below the plurality of horizontal wordlines, the plurality of vertical bitlines, and the plurality of memory elements.

16. The memory array of claim 1, wherein the plurality of vertical bitlines is coupled to the underlying substrate without additional routing layers.

17. The memory array of claim 1, further comprising:
a second plurality of horizontal wordlines disposed in a second plane above and parallel with the first plane, wherein the plurality of vertical bitlines is also interposed with the second plurality of horizontal wordlines to provide a second plurality of cross-points between ones of the second plurality of horizontal wordlines and ones of the plurality of vertical bitlines; and
a second plurality of memory elements disposed in the second plane, one memory element disposed at each cross-point between the corresponding wordline and bitline of the cross-point.

18. A conductive-oxide random access memory (CORAM) array, comprising:
a plurality of cross-points in a horizontal plane above a substrate, each cross-point formed from a corresponding horizontal wordline and vertical bitline; and
a plurality of CORAM elements, each CORAM element disposed at a corresponding one cross-point.

19. The CORAM array of claim 18, wherein each of the plurality of CORAM elements includes an anionic-based conductive oxide memory layer.

20. The CORAM array of claim 18, wherein each of the plurality of CORAM elements includes a cationic-based conductive oxide memory layer.

21. The CORAM array of claim 18, further comprising:
a second plurality of cross-points in a second horizontal plane above the first horizontal plane, each cross-point formed from a corresponding horizontal wordline and vertical bitline; and
a second plurality of CORAM elements, each CORAM element disposed at a corresponding one cross-point of the second plurality of cross-points, wherein a same bitline couples one CORAM element of the first plurality of CORAM elements and one CORAM element of the second plurality of CORAM elements.

22.-25. (canceled)
